(19) United States
(12) Patent Application Publication
(10) Pub. No.: US 2010/0252880 A1
(43) Pub. Date: Oct. 7, 2010

(54) METHOD OF MANUFACTURING A SEMICONDUCTOR DEVICE, AND A SEMICONDUCTOR DEVICE

(75) Inventor: Paul Ronald Stribley, Devon (GB)

Correspondence Address: SNELL & WILMER L.L.P. (Main), 400 EAST VAN BUREN, ONE ARIZONA CENTER, PHOENIX, AZ, 85004-2202, US

(73) Assignee: X-FAB SEMICONDUCTOR FOUNDRIES AG, Erfurt (DE)

(21) Appl. No.: 12/669,728

(22) PCT Filed: Jul. 18, 2008
(86) PCT No.: PCT/GB2008/050598

§ 371 Date: Jun. 17, 2010

(30) Foreign Application Priority Data
Jul. 20, 2007 (GB) 0714071.8

(51) Int. Cl. H01L 29/78; H01L 21/20; H01L 21/22; H01L 29/06; H01L 21/336; H01L 21/24

(52) U.S. Cl. 257/335; 438/508; 438/506; 257/607; 438/197; 257/E21.417; 257/E29.256; 257/E29.024; 257/E21.09; 257/E21.135; 257/E21.154

(57) ABSTRACT

A method of manufacturing a semiconductor device comprises the steps of, in sequence: depositing a first silicon layer; patterning the first silicon layer to obtain a first silicon region; implanting a first dopant into a first part of the first silicon region, the first part of the first silicon region defined using a first mask; depositing a second silicon layer; patterning the second silicon layer to obtain a second silicon region; and implanting a second dopant into a second part of the first silicon region, the second part of the first silicon region defined by the first mask and the second silicon region.

A device comprises a semiconductor layer (6); a first doped region (5) within the semiconductor layer; a second doped region (7) within the first doped region (5); and a silicon layer (9) disposed over a part of the semiconductor layer; wherein the silicon layer is disposed over a part of the first doped region (5) but not over the second doped region (7).

The present invention relates to a method of manufacturing a semiconductor device, in particular to manufacturing a semiconductor device using silicon-based CMOS processes. It also relates to a semiconductor device obtained by the method of the invention.

Silicon-based CMOS (complementary metal-oxide-silicon) processes used in mainstream semiconductor IC (integrated circuit) manufacture often use two polysilicon layers. The first polysilicon layer is used for gates of transistors. The second polysilicon layer is usually used for passive components such as resistors and capacitors. Integration of a process using two polysilicon layers may be done in a variety of ways; the capacitor layer may be deposited and etched either before or after the gate layer.

Another feature which is commonly found is the self-alignment of the source and drain diffusion connections of a transistor to the polysilicon gate of the transistor. To do this the polysilicon is etched to form a gate which has a desired shape, and which is positioned over an active semiconductor areas with a thin gate dielectric between. Then, the source and drain regions are defined in the active area using an n+ or p+ implant (for NMOS or PMOS respectively). The gate is used as an implant stop during the implantation process, to block implanted dopants which otherwise enter the active area to form the source and drain regions. Sub-micron CMOS processes usually incorporate a dielectric spacer region on the edges of the polysilicon gate, which is used to offset the heaviest doping from the gate by a small distance. Another implant, an LDD (lightly doped diffusion) implant, is used, self-aligned to the polysilicon, before the spacer is formed to ensure that the transistor channel is electrically connected to the source and drain diffusion. The LDD is the “lightly doped diffusion” zone which has the same conductivity type as the source and drain regions but has a lower doping level. Very often, the LDD implant and the Source-Drain implant use the same photolithographic pattern—just printed at the different process stages. Access to areas receiving the LDD implant alone can therefore be very difficult; they are often only found on the edges of the transistors.

As an example, US2005/0045883 discloses a method of fabricating a thin film semiconductor device in which a metallic gate is deposited and patterned on a polycrystalline silicon layer. The portions of the polycrystalline silicon layer that are not covered by the gate are then implanted to form a LDD region and/or a source or drain region. The LDD region and the source/drain region may for example be formed in self-alignment with the gate electrode.

A first aspect of the present invention provides a method of manufacturing a semiconductor device comprising, in sequence:
depositing a first silicon layer;
patterning the first silicon layer to obtain a first silicon region;
implanting a first dopant into a first part of the first silicon region, the first part of the first silicon region being defined using a first mask;
depositing a second silicon layer;
patterning the second silicon layer to obtain a second silicon region; and
implanting a second dopant into a second part of the first silicon region, the second part of the first silicon region being defined by the first mask and the second silicon region.

It should be noted that specifying that the first dopant is implanted into a “first part” of the first silicon region does not require that the first dopant is implanted only into a single part of the first silicon region, but also covers a case where the first dopant is implanted into two or more discrete parts of the first silicon region. (This is also true for the feature of implanting the second dopant into the “second part” of the first silicon region.) Furthermore, the reference to implanting the first dopant into a “first part” of the first silicon region does not exclude the case that the first part of the first silicon region is equal or substantially equal to the whole of the first silicon region.

In the invention the second silicon layer, for example a capacitor polysilicon layer in a CMOS process that uses two polysilicon layers, is deposited and etched after the first silicon layer, for example a gate polysilicon layer in a CMOS process that uses two polysilicon layers, has been deposited, patterned and etched. However the first implantation step, which may for example form one or more LDD implants (n− or p−), is carried out after the first silicon layer is etched, but before the second silicon layer is deposited.

Since the second silicon layer is deposited after the first implantation step (which are, for example, to form the LDD implant(s)) it becomes possible for second silicon layer to effectively block a further implantation step into part of the doped area formed by the first implantation step whilst still allowing the same photolithographic mask shapes to define the areas that are implanted—for example, if a second implantation step is carried out after deposition of the second silicon layer to implant n+ or p+ donors to define source and drain regions in the LDD implant(s), the second silicon layer will act as a mask in this implantation step. The area masked by the second silicon layer may be a semiconductor active area or the first silicon layer itself.

Therefore the position of the second silicon layer (eg capacitor polysilicon layer) in the process flow allows larger areas of LDD implanted semiconductor, or silicon. In particular, since the LDD implant(s) are formed before the second silicon layer is deposited, it is possible for the LDD implant(s) to extend under the second silicon region. These may be configured to create many useful electronic devices. The ability to self-align a subsequent n+ or p+ implantation to the capacitor polysilicon also gives further device options.

If the first silicon layer is undoped or lightly doped then it can be utilised in a number of ways to create MOSFETs, resistors or diodes using the LDD and source-drain implants in conjunction with the second silicon layer.

Preferably a dielectric layer (or other insulating layer) is provided between the first silicon layer and the second silicon layer. This is used to electrically isolate the two silicon layers from one another.

In a further preferred embodiment, a spacer dielectric may be created at one or both sides of the second silicon layer. In this embodiment, the mask for the second implantation step is constituted by the spacer dielectric and the second silicon layer.

The first and second silicon layers may be polysilicon layers as mentioned above, or one or both of the first and second silicon layers may be amorphous silicon layers.

A second aspect of the present invention provides a method that is complementary to the method of the first aspect, but in which the device structure is defined in a body diffusion in a substrate.

A third aspect of the present invention provides a method of manufacturing a semiconductor device comprising, in sequence:
a) forming a body diffusion in a substrate;
b) depositing a first silicon layer;
c) patterning the first silicon layer to form a first silicon region;
d) implanting a first dopant into a first part of the body diffusion, the first part of the body diffusion defined using a first mask and the first silicon region;
e) depositing a second silicon layer;
f) patterning the second silicon layer to form a second silicon region; and
g) implanting a second dopant into a second part of the body diffusion, the second part of the body diffusion being defined by the first mask and the second silicon region.

The first and second silicon layers may be polysilicon layers as mentioned above, or one or both of the first and second silicon layers may be amorphous silicon layers.

A fourth aspect of the present invention provides a method of manufacturing a semiconductor device comprising, in sequence:
depositing a first silicon layer;
patterning the first silicon layer to obtain a first silicon region;
implanting a first dopant into a first part of the first silicon region to obtain a lightly-doped diffusion region in the first part of the first silicon region;
depositing a second silicon layer;
patterning the second silicon layer to obtain a second silicon region; and
implanting a second dopant into a part of the lightly-doped diffusion region using the second silicon region as a mask.

In this aspect of the invention it is again possible for the LDD region(s) to extend under the second silicon region, since they are formed before the second silicon layer is deposited. The portion(s) of the LDD region(s) that lie under the second silicon region are protected against implantation of the second dopant since the second silicon region acts as a mask.

The first and second silicon layers may be polysilicon layers as mentioned above, or one or both of the first and second silicon layers may be amorphous silicon layers.

A fifth aspect of the present invention provides a method that is complementary to the method of the fourth aspect but that relates to manufacturing a semiconductor device in a body diffusion formed in a substrate.

A sixth aspect of the present invention provides a device comprising: a semiconductor layer; a first doped region within the semiconductor layer; a second doped region within the first doped region; and a silicon layer disposed over a part of the semiconductor layer; wherein the silicon layer is disposed over a part of the first doped region but not over the second doped region.

The silicon layer may be a polysilicon layer or an amorphous silicon layer.

Other preferred features of the invention are set out in the dependent claims.

Preferred embodiments of the present invention will now be described by way of illustrative example with reference to the accompanying figures in which:

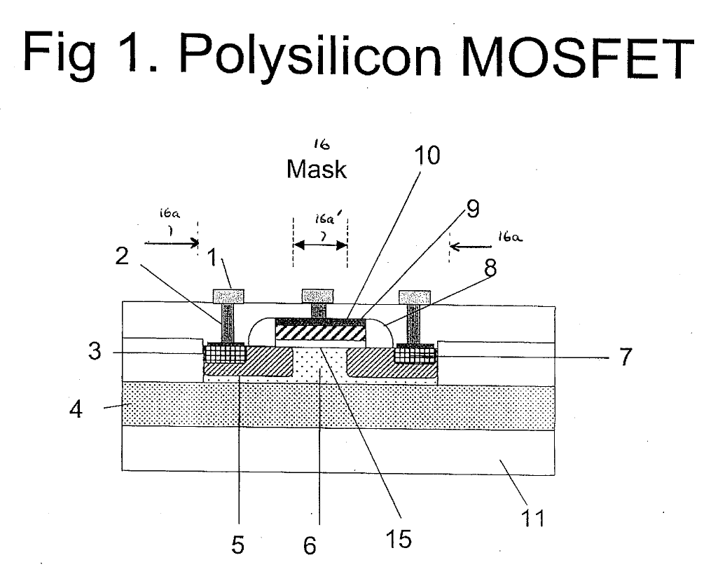

FIG. 1 is a schematic sectional view of a MOSFET according to an embodiment of the present invention;

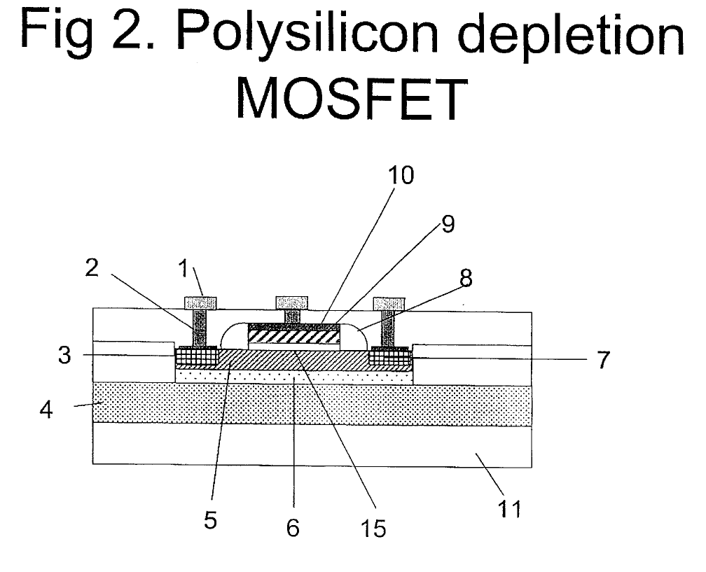

FIG. 2 is a schematic sectional view of a MOSFET according to another embodiment of the present invention;

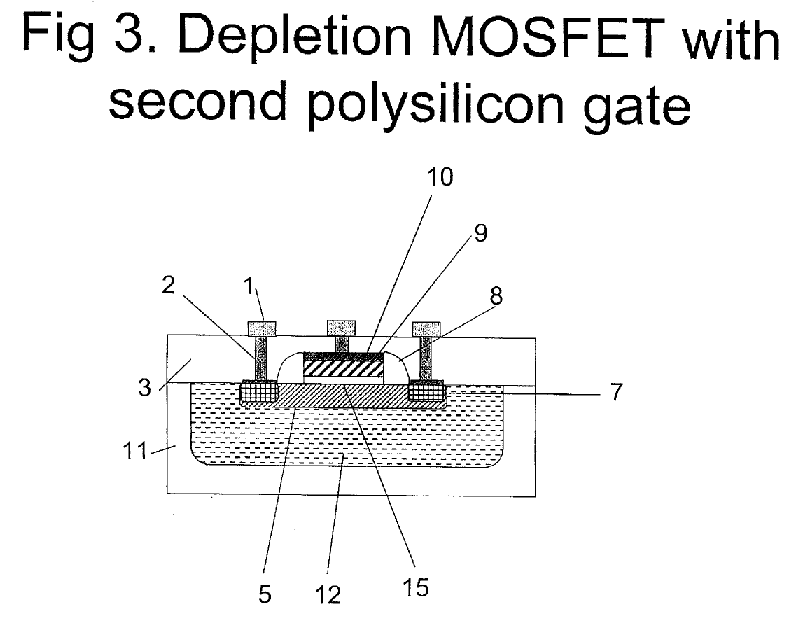

FIG. 3 is a schematic sectional view of a MOSFET according to another embodiment of the present invention;

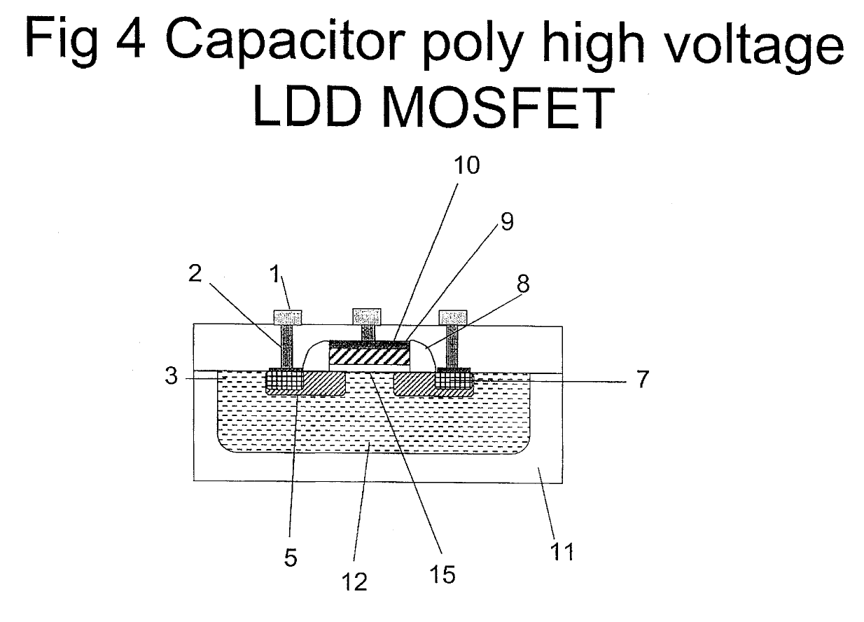

FIG. 4 is a schematic sectional view of a MOSFET according to another embodiment of the present invention;

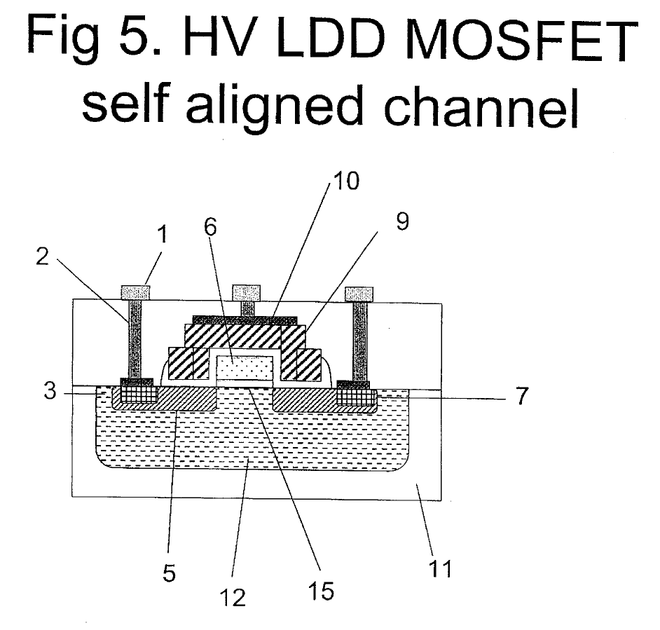

FIG. 5 is a schematic sectional view of a MOSFET according to another embodiment of the present invention;

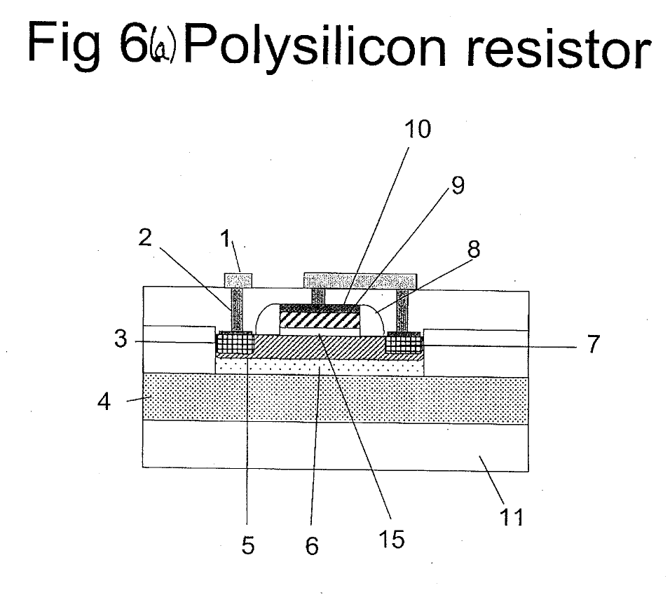

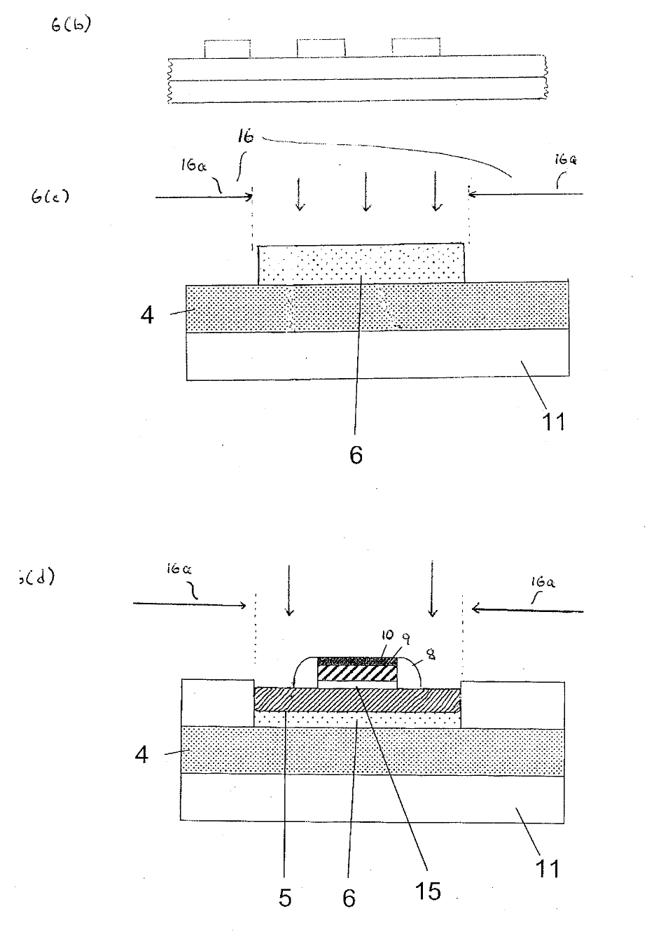

FIG. 6(a) is a schematic sectional view of a resistor according to another embodiment of the present invention;

FIGS. 6(b), 6(c) and 6(d) illustrate steps in the manufacture of the resistor of FIG. 6(a);

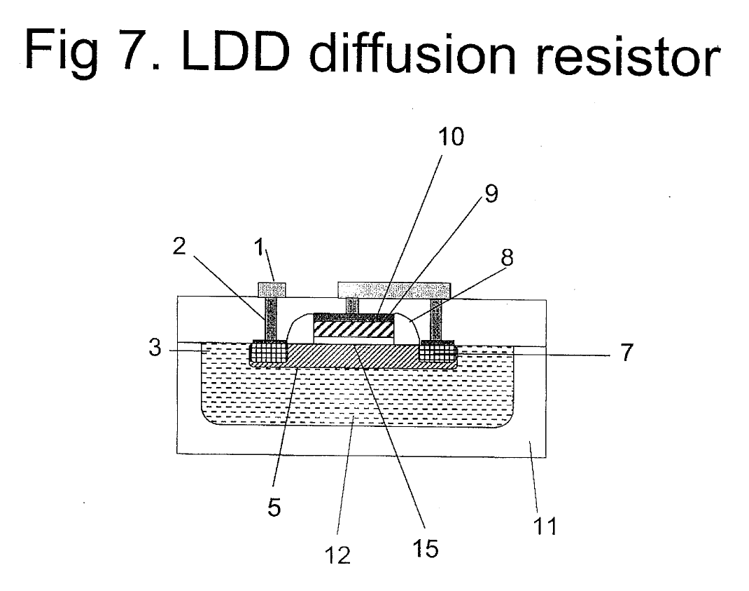

FIG. 7 is a schematic sectional view of a resistor according to another embodiment of the present invention;

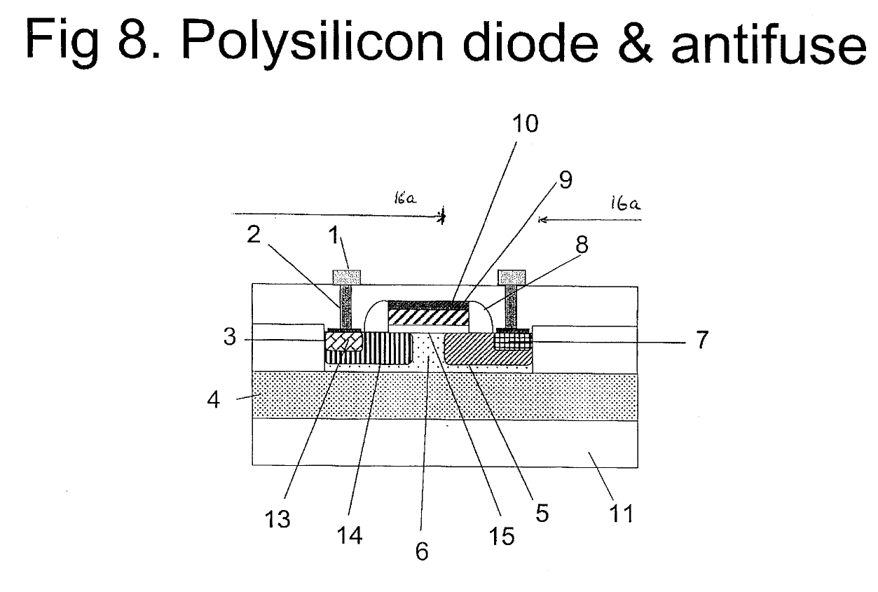

FIG. 8 is a schematic sectional view of a diode according to another embodiment of the present invention;

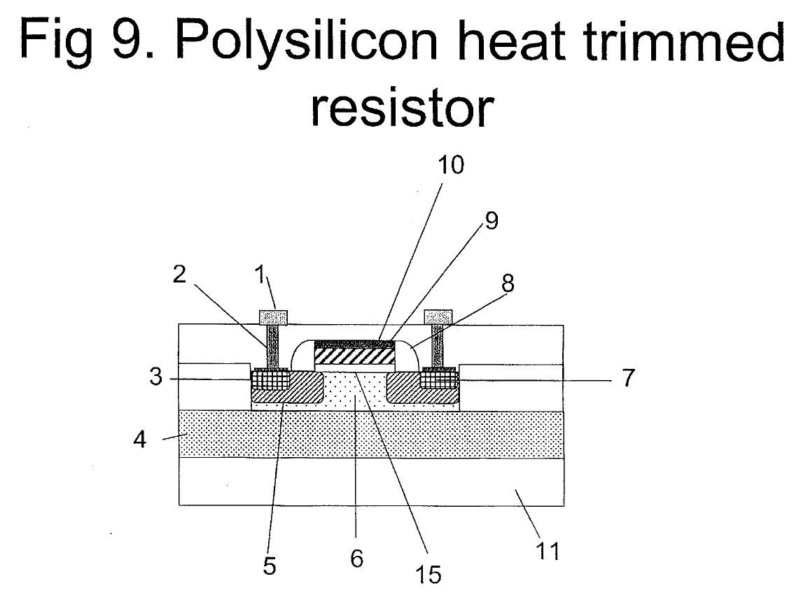

FIG. 9 is a schematic sectional view of a resistor according to another embodiment of the present invention;

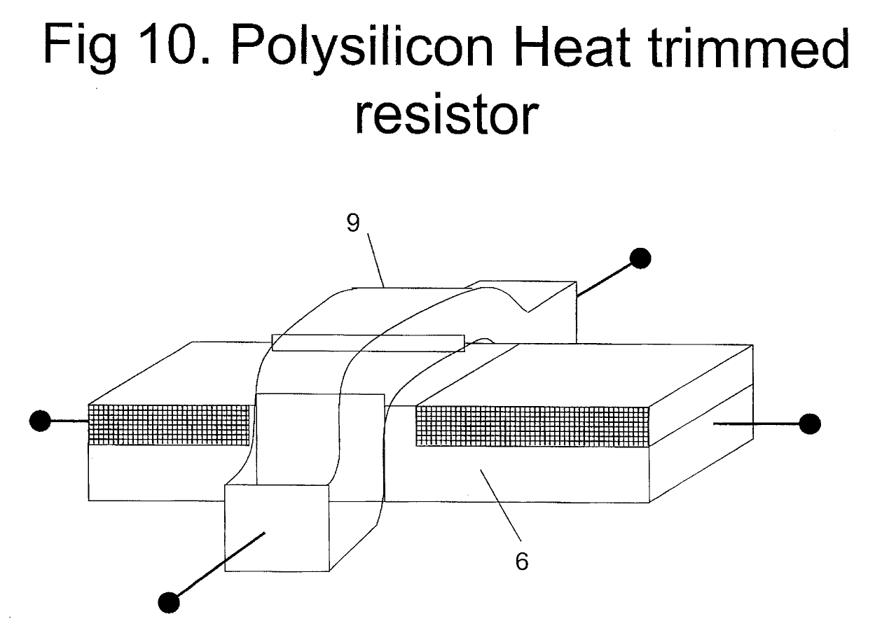

FIG. 10 is a schematic perspective view of a resistor according to another embodiment of the present invention;

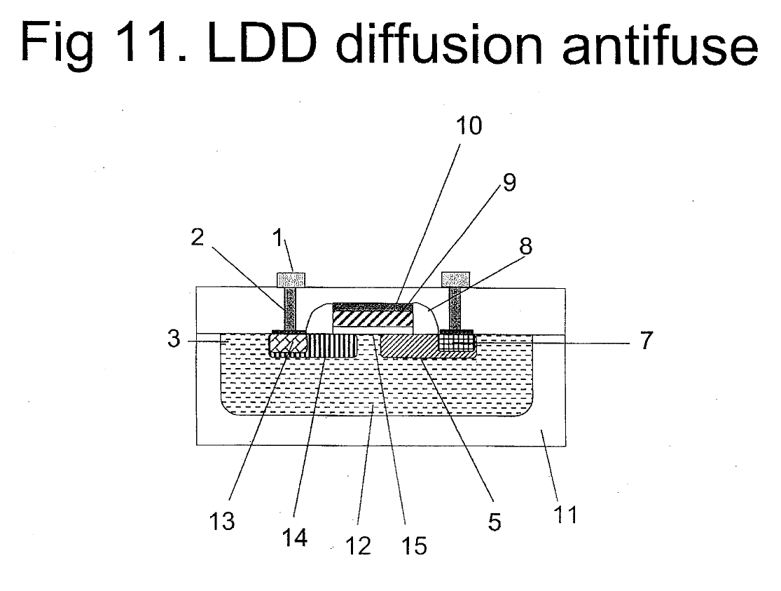

FIG. 11 is a schematic sectional view of an antifuse diode according to another embodiment of the present invention;

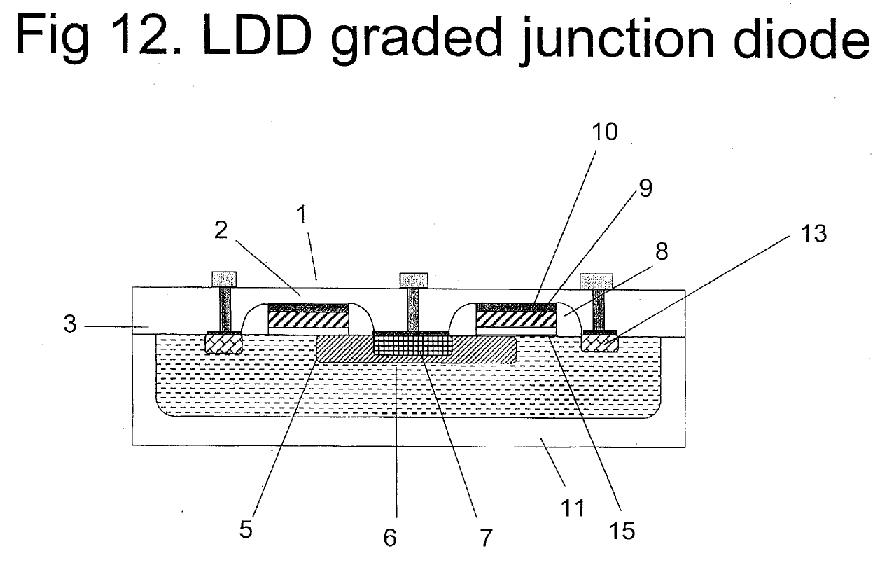

FIG. 12 is a schematic sectional view of a diode according to another embodiment of the present invention;

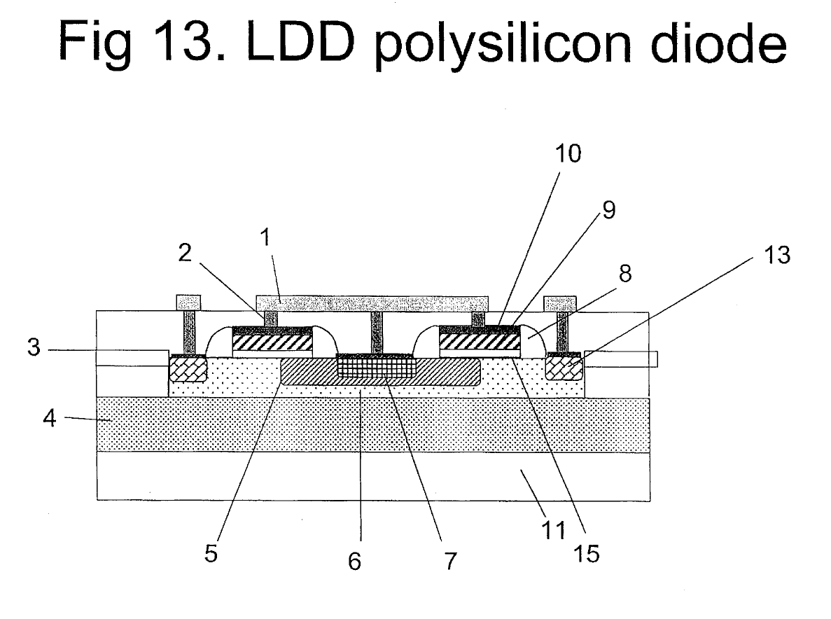

FIG. 13 is a schematic sectional view of a diode according to another embodiment of the present invention;

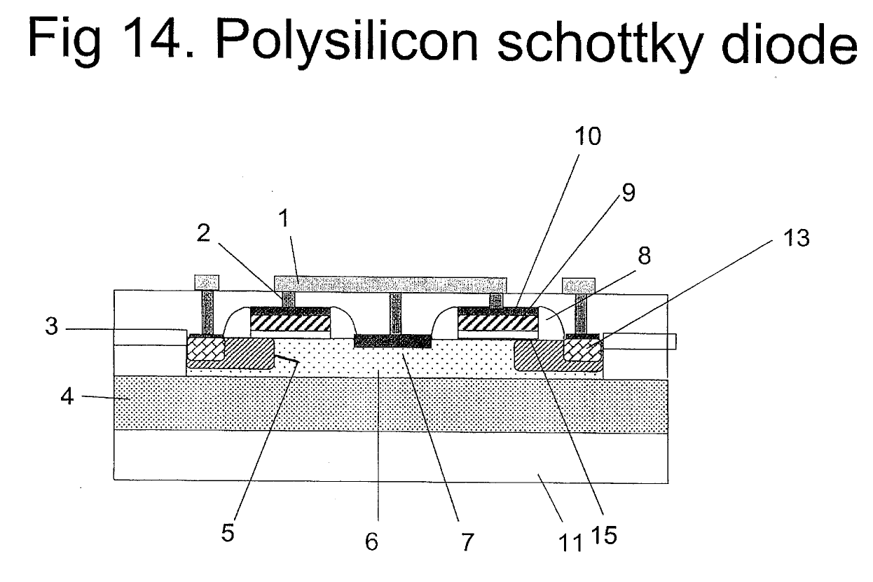

FIG. 14 is a schematic sectional view of a diode according to another embodiment of the present invention; and

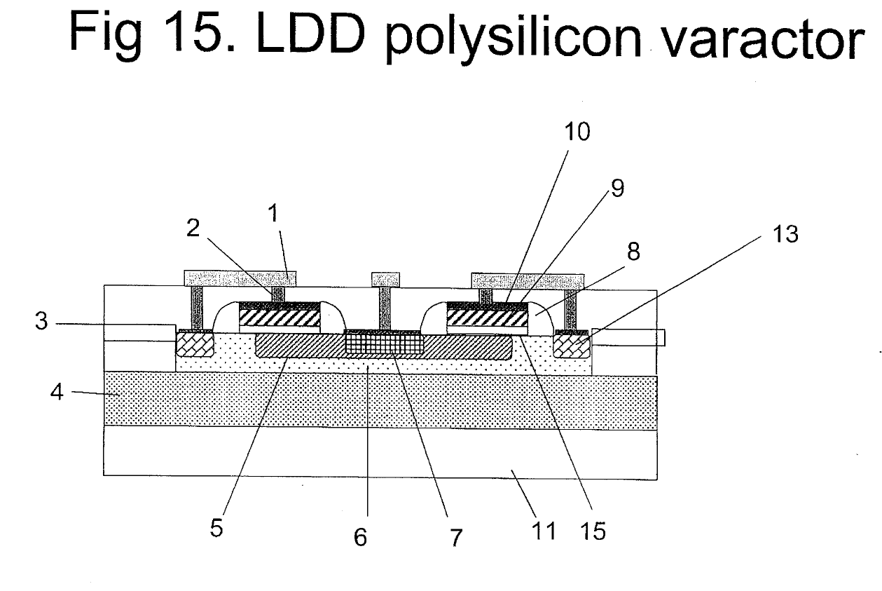

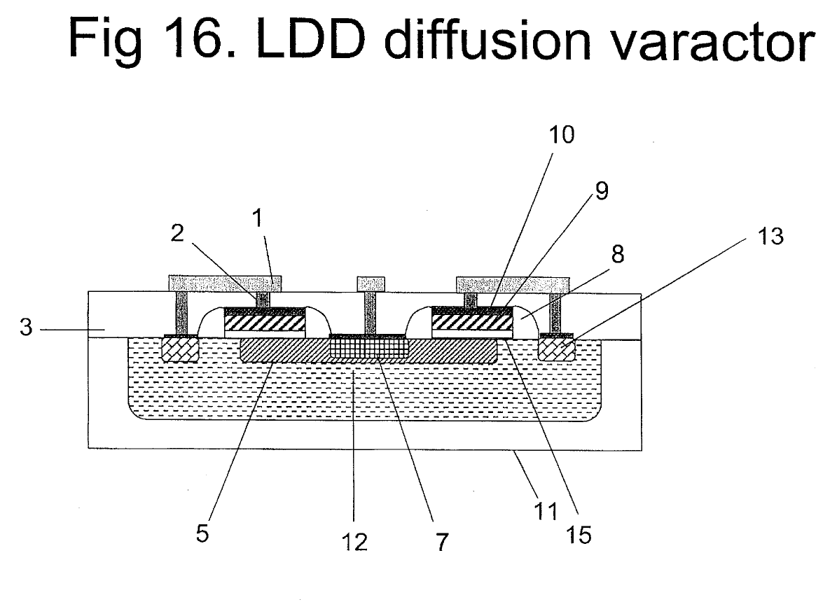

FIG. 15 is a schematic sectional view of a varactor structure according to another embodiment of the present invention;

In the figures the following structures are labelled:
1 Metal wiring;
2 Contact metal;
3 Dielectric insulator between a device and a metallisation;
4 Dielectric insulator (field region);
5 LDD implant diffusion (n− or p−);
6 First polysilicon layer (gate polysilicon); very lightly doped;
7 Contact/source/drain n+/p+ doping diffusion;
8 Spacer dielectric;
9 Second polysilicon layer (capacitor polysilicon); doped;
10 Silicide;
11 Semiconductor wafer substrate;
12 Body diffusion (lightly doped well—opposite doping type to 5);
13 Source/drain implant: p+ or n+; opposite doping type to 5;
14 LDD implant; opposite doping type to 5 (p− or n−);
15 Gate dielectric layer;
16 Implantation Mask;
16a Blocking portion of mask

FIG. 6(a) is a schematic sectional view of a resistor according to an embodiment of the present invention. The principal steps of the method of fabricating the resistor of figure are as follows:

Initially, an insulating layer 4, for example a dielectric layer, is deposited over a substrate 11, for example a semiconductor wafer. The insulating layer 4 forms a field region.

A first silicon layer 6, in this example a polysilicon layer 6, is then deposited over the insulating layer 4, and is patterned/etched to a desired shape using any suitable masking technique and patterning/etching technique. If desired, the first polysilicon layer 6 may then be doped at a very light doping level (which may be either p-type or n-type).

The first polysilicon layer 6 is then etched to define a plurality of isolated first polysilicon regions. FIG. 6(b) shows the first polysilicon layer after it has been etched to form a plurality of discrete regions. Each region will be incorporated in one device, and forms the “body” of the device. The shape (as seen in plan view) of the first polysilicon regions will depend on the type of device to be manufactured.

Further description of the fabrication method will describe only the method as applied to one of the first polysilicon regions obtained when the polysilicon layer 6 is etched. In practice, as is conventional in semiconductor device processing, a plurality of first polysilicon regions 6 will be defined and each will be processed to form a device.

A first implantation step is then performed to implant a dopant into a desired region of the first polysilicon region obtained by patterning the first polysilicon layer. In this example, the first implantation step is performed to form an LDD region. FIG. 6(a) shows one LDD region 5 that extends over substantially the entire area of the first polysilicon region, but the method is not limited to this (as shown, for example, by FIG. 1). In this implantation step, an implantation mask 16 is defined and the first dopant is implanted into the first polysilicon region through the aperture(s) of the implantation mask. The implanted dopant cannot pass through the blocking portions 16a of the implantation mask, and regions under the blocking portions 16a of the mask are therefore not implanted in this implantation step. Depending on the desired device, the LDD region may be defined using either a p-type dopant or an n-type dopant. The doping level in the LDD region 5 is greater than the doping level of the initial implantation step (if present).

It should be noted that the aperture of the mask used in the first implantation step is preferably slightly greater than the desired area into which the dopant is to be implanted, to allow for overlay tolerancing in the manufacturing process.

The first implantation step is shown in FIG. 6(c). It should be noted that the implantation mask is shown only schematically in figure (c), and a more detailed description of the mask used is given below.

A second insulating layer 15, for example a second dielectric layer and a second silicon layer 9, for example, a polysilicon layer 9, are then deposited over the insulating layer 4, and are patterned/etched to give a second polysilicon region of a desired shape using any suitable masking technique and patterning/etching technique. The second polysilicon region extends over some, but not all, of the LDD region(s) formed in the first polysilicon layer, and may, in the eventual device, act as a gate. In general, the second polysilicon region may be doped, for example by doping the second polysilicon layer before it is patterned.

Next, a spacer dielectric 8 (or other insulator) is deposited on part (but not all) of the part of the first polysilicon region that is not covered by the second polysilicon region, to form a sidewall spacer. The spacer dielectric 8 may be deposited by any suitable technique.

Next, a second implantation is carried out to form contact regions 7 in the first polysilicon layer, to make ohmic contacts to the LDD region. The second implantation will generally implant, into an LDD region, a dopant of the same conductivity type as implanted to form the LDD region, but the contact regions will be more heavily doped, and so will have a higher free carrier concentration, than the LDD region. The second implantation step is shown in FIG. 6(d).

The second implantation step is carried out using an implantation mask that is the same as the implantation mask 16 as was used in the first implantation step of FIG. 6(c). (As is described in more detail below the implantation mask used in the first step is not re-used and a new implantation mask is defined for the second implantation step but the implantation mask defined for the second implantation step is, within the limits of manufacturing tolerance, identical to the implantation mask used in the first implantation step.) However, the implanted dopants are blocked by the second polysilicon region 9 and the spacer dielectric region(s) 8. Dopants are therefore implanted only into the part of the first polysilicon region that is not covered by the second polysilicon region 9 or the spacer dielectric region(s) 8. This leads to the contact regions 7 having the shape shown in FIG. 6(a).

In the second implantation step, the second polysilicon region (and spacer dielectric region(s) 8) combine with the implant mask 16 to ensure that the second implant is aligned with the edges of the second polysilicon region layer (or with the edges of the spacer dielectric 8). However, this restriction is not present in the first implantation step of FIG. 6(c), and this makes it possible for the area of the first polysilicon region that is implanted in the first implantation step to be independent of the part(s) of the first polysilicon region that are implanted in the second implantation step. This allows much greater freedom in, for example, the position of the LDD region. However, by making use of the same mask 16 in both the first and second implantation steps, there is no need to use a different mask in the second implantation step, and the cost of an extra mask is therefore avoided.

The structure may then be thermally annealed, to activate the dopants implanted in each of the implantation steps.

Next, a silicide layer 10 is formed so as to be co-extensive with the second polysilicon region 9. The silicide layer 10 reduces the contact resistance. It may be formed by depositing a metal layer, and thermally cycling the structure so that a silicide layer forms at the interface between the metal and the second polysilicon region 9. The unreacted part of the metal layer is then removed to leave the silicide layer.

Finally an insulating layer 3, for example a dielectric layer, is deposited over the structure, vias 2 are formed through the insulating layer 3 to the source and drain regions and to the silicide layer 10. Contact metal 2 is deposited in the vias, and to form contacts 1 on the upper surface of the insulating layer.

In a conventional method in which a patterned polysilicon layer is used as the mask for an LDD implantation and the same polysilicon layer and a spacer dielectric are together used as the mask an implantation to form contact regions, the area of the LDD implant region(s) can exceed the area of the contact regions only by the area covered by the spacer dielectric—so that the area receiving the LDD implant but not a source/drain implant is small. In contrast, in the method of the present invention the polysilicon layer is not used as a mask in the LDD implantation process—indeed the LDD implantation process is performed before the second polysilicon layer is deposited. The LDD region(s) may therefore cover any desired part of the first polysilicon layer.

It should be noted that where the LDD region extends over the entire area, or substantially the entire area, of the first polysilicon layer, as in the device of FIG. 6(a), it may be possible to omit the initial step of doping the first polysilicon layer to a very low doping level. The initial step of doping the first polysilicon layer to a low doping level is, however, preferably carried out in embodiments in which the LDD region does not extend over the entire first polysilicon region.

As was noted above, the implantation mask 16 shown in FIGS. 6(c) and 6(d) is schematic. In practice, a light-sensitive chemical known as a “resist” is spread very thinly over the entire device, and this is exposed to light through a master template called a “mask” or “reticle”, for example using a photolithographic stepper. This mask will be referred to as the “resist exposure mask”, to distinguish it from the implantation mask 16 of FIG. 6(c) or FIG. 6(d).

A resist may be either a positive photoresist or a negative photoresist. In a positive photoresist the portion of the photoresist that is exposed to light becomes soluble to a suitable developer and the portion of the photoresist that is unexposed remains insoluble to the developer. In a negative photoresist conversely, the portion of the photoresist that is exposed to light becomes relatively insoluble to the photoresist developer whereas the unexposed portion of the photoresist is dissolved by the photoresist developer. It is generally preferred to use a negative photoresist in semiconductor fabrication processes, since a negative photoresist has better adhesion to silicon and is cheaper than a positive photoresist, and the invention will therefore be described with reference to use of a negative photoresist. In principle, however, a positive photoresist could be employed.

To form the implantation mask 16, therefore, a layer of negative photoresist would be disposed over the first polysilicon region 6 and the exposed portions of the insulator 4. This layer of photoresist would then be exposed to light wherever it was intended to form a blocking portion 16a of the implantation mask 16. This may be done by exposing the layer of negative photoresist through a photoresist exposure mask that is the opposite to the desired implantation mask—that is, the photoresist exposure mask has opaque portions where the implantation mask 16 is desired to have apertures and the photoresist exposure mask has transparent portions where the implantation mask 16 is desired to have blocking portions 16a. When the negative photoresist layer is treated with a developer after exposure, the regions that were not exposed to light are dissolved to leave the aperture in the implantation mask 16 whereas the exposed portions of the photoresist resist the developer and form the blocking portions 16a of the implantation mask.

After the implantation step has been carried out, the resist may be removed by a suitable solvent before the second insulating layer 15 is deposited.

For completeness, it should be noted that a photoresist mask may also be used to pattern a polysilicon layer, by treating the photoresist such that, after development, the resist is present in regions where it is desired to retain the polysilicon layer. The wafer may then be exposed to a reactive plasma (a low density of reactive ions) which etches the polysilicon where it is not protected by the resist. If the plasma is applied for long enough, the regions of the polysilicon that are not protected by the resist are completely removed. The residual resist may then be removed before the next fabrication step.

In the method of the invention, the same implantation mask 16 is used in the first implantation step as in the second implantation step, in that the implantation mask used in the first implantation step is the same (within the limits of manufacturing tolerance) as the mask used in the second implantation step. This means that only one photoresist exposure mask is required to create both the implantation mask for the first implantation step and the implantation mask for the second implantation step.

FIG. 7 is a schematic sectional view of another resistor according to another embodiment of the present invention. This corresponds generally to the resistor of FIG. 6, except that the LDD region(s) and contact regions are formed in a body diffusion 12 formed in the substrate 11. The body diffusion is a lightly doped region, of opposite doping type to the LDD implant 5.

The resistor of FIG. 7 may be formed by a conventional CMOS process involving deposition of two layers of polysilicon, although the first polysilicon layer is removed completely from the part of the wafer where the resistor is formed. The LDD region 5 is formed after deposition of the first polysilicon layer, and the second polysilicon layer (and spacer dielectric, if present) are used as the mask in the second implantation process to form the contact regions.

FIG. 1 is a schematic sectional view of a MOSFET according to an embodiment of the present invention. The MOSFET of FIG. 1 is generally similar to the resistor of FIG. 6, except that the LDD implantation does not extend across the entire width of the first polysilicon region (and in that the metal wirings 1 are deposited to form separate contacts to the source region, drain region and the second polysilicon layer). The part of the first polysilicon region between the two LDD regions form the channel region of the MOSFET. The second polysilicon region forms the gate of the MOSFET, with the source and drain either side. There are two LDD regions, separate from one another, of which one contains the source contact region and one contains the drain contact region. Both LDD regions extend under the second polysilicon region 9.

The method of manufacturing the MOSFET of FIG. 1 is generally similar to the method of manufacturing the resistor of FIG. 6(a). The principal different is that the implantation step to form the LDD region is carried out using a mask that defines the two separate LDD regions. Compared with the mask 16 used in FIG. 6(b) or 6(c), the implantation mask required in FIG. 1 has a further blocking region 16a that prevents the LDD region extending over the entire first polysilicon region and leads to the formation of two separated LDD regions.
By creating polysilicon transistors there are advantages in complete isolation from the substrate—allowing higher voltages, and also lower parasitic capacitances to the substrate which improves switching speed. The current drive in this device is lower than in single crystal silicon however, due to the lower mobility of carriers. Threshold voltages vary depending on the polysilicon doping and gate dielectric capacitance.

The longer LDD regions provided by the invention tend to allow greater operating voltages by being able to deplete further and also add some series resistance which lowers the electric field in the source-drain region.

By combining an inner first polysilicon region to define the channel length (the separation between the LDD regions) and then using, as the MOSFET gate, a second polysilicon region having greater area than the LDD separation and which overlies the first polysilicon region, but dictates the position of the source and drain regions, makes possible a high voltage device. The MOSFET of FIG. 1 has the advantage of self aligned channel to gate and also of a user defined length for the LDD region.

A variant would be for the second polysilicon region to overlap the LDD region on the drain side only. This would give an asymmetric device, allowing higher voltages only on the drain.

FIG. 4 is a schematic sectional view of a MOSFET according to another embodiment of the present invention. The MOSFET of FIG. 4 is generally similar to the MOSFET of FIG. 1, except that the LDD regions and source and drain regions are formed in a body diffusion 12 formed in the substrate 11.

FIG. 5 is a schematic sectional view of a MOSFET according to another embodiment of the present invention. The MOSFET of FIG. 5 is similar to the MOSFET of FIG. 4, in that the LDD regions and source and drain regions are formed in a body diffusion 12 formed in the substrate 11. In the manufacture of this MOSFET, the first polysilicon layer 6 is deposited over the body diffusion (with an insulating layer 15 present therebetween), and is patterned to give a first polysilicon region to act (in combination with a suitable implant mask) as the mask during the LDD implantation step. The patterned first polysilicon region is not removed, and the second polysilicon layer 9 is deposited over the first polysilicon region 6 (with an insulating layer present therebetween) and patterned. The resultant second polysilicon region 9 extends substantially along side faces of the first polysilicon layer 6, so that the second polysilicon region 9 “encloses” the first polysilicon region 6.

The manufacture of the MOSFET of FIG. 5 again involves a second implantation step to obtain the source/drain contact regions. The same implantation mask is used for the second implantation step as was used for the first implantation step, in combination with the second polysilicon region 9.

In the MOSFET of FIG. 5, the second polysilicon region 9 is electrically connected to the first polysilicon region 6, so that the first polysilicon region 6 and the second polysilicon region 9 together form the gate of the MOSFET. Since the gap between the two LDD regions is defined by the first polysilicon region in the LDD implantation process no separate mask is needed for the LD implantation. However, since the gate is defined by the combination of the first polysilicon region 6 and the second polysilicon region 9 the length of the LDD regions can be chosen to be any desired length.

FIG. 2 is a schematic sectional view of a MOSFET according to another embodiment of the present invention. The MOSFET of FIG. 2 is generally similar to the MOSFET of FIG. 1, except that the LDD region extends across the entire width of the first polysilicon region, so that the source and drain regions are formed in the same LDD region. The MOSFET of FIG. 2 is therefore a depletion MOSFET since there is a conductive channel between the source region and the drain region with no voltage applied to the gate (formed by the second polysilicon layer), and an applied gate voltage will vary the depletion of the semiconductor beneath it.

The method of manufacturing the MOSFET of FIG. 2 is generally similar to the method of manufacturing the MOSFET of FIG. 1. The principal different is that the implantation step to form the LDD region is carried out using an implantation mask which causes the whole of the first polysilicon layer to be doped with the LDD implant thereby defining a single LDD region in the first polysilicon layer.

FIG. 3 is a schematic sectional view of a MOSFET according to another embodiment of the present invention. The MOSFET of FIG. 3 is generally similar to the MOSFET of FIG. 2, except that the LDD regions and source and drain regions are formed in a body diffusion 12 formed in the substrate 11, and is again a depletion mode MOSFET.

The MOSFETS of FIGS. 1 and 2, or FIGS. 3 and 4, may be used to construct a simple ROM memory which can be programmed using the LDD implant mask. The memory comprises an array of MOSFETs, in which each individual MOSFET is selected to be made either as a normal transistor type or as a depletion transistor type, by providing implant mask gaps for the conducting channel or not. Then a simple conduction check with small gate bias voltage can easily read a bit of the memory to see if a bit is “1” or “0”.

FIG. 8 is a schematic sectional view of a diode according to another embodiment of the present invention. The diode of FIG. 8 is generally similar to the MOSFET of FIG. 1 in that two LDD regions 5,14 are formed in the first polysilicon region, such that one LDD region 5 is separated from the other LDD region 14 by a part of the first polysilicon region into which no dopants were implanted in the LDD implantation step. In the diode of FIG. 8, however, the two LDD regions are implanted with different dopants and so have opposite conductivity types to one another (denoted in FIG. 8 by the different shading of the two LDD regions). In the MOSFET of FIG. 1, in contrast, the two LDD regions have the same conductivity type.

Also, no contact metal or metal wiring to the second polysilicon layer 9 need be provided in the diode of FIG. 8.

A contact region in an LDD region of the diode of FIG. 8 has the same conductivity type as the LDD region in which it is formed, to prevent a p:n junction being set up at the boundary between the contact region and the LDD region. This means that one contact region of the diode of FIG. 8 has the opposite conductivity type to the other contact region of the diode of FIG. 8.

The process of manufacturing the diode of FIG. 8 is generally similar to the process of manufacturing the resistor of FIG. 6, except that two separate implantation steps using appropriate masks are required to form the two LDD regions 5, 14, and two separate implantation steps are required to form the contact regions 7,13. In one LDD implantation step the first polysilicon region 6 is masked except for a part that is intended to become one of the LDD regions, and the appropriate dopant is implanted. The first polysilicon region 6 is then re-masked, such that a part that is intended to become the other LDD region is exposed and the remainder is masked, and the appropriate dopant is implanted to form the other LDD region.

An implant mask suitable for defining the right-hand LDD region of FIG. 8 is shown schematically in FIG. 8. As can be seen this has blocking portions 16a everywhere except over the desired position of the right-hand LDD region 5. A corresponding mask having blocking portions everywhere except over the desired position of the left-hand LDD region 14 would be used to obtain the left-hand LDD region 14.

In the implantation step to form the right-hand contact region 7, the implantation mask shown in FIG. 8 is again used. This acts in combination with the second polysilicon region 9 and the right-hand spacer dielectric 8 to ensure that, in the second implantation step, dopants are implanted only into the right-hand contact region 7 and are not implanted into the entire right-hand LDD region 5.

Finally, there is a further implantation step using the implant mask used to obtain the left-hand LDD region. In this implant step the implant mask acts in combination with the second polysilicon region 9 and the left-hand spacer dielectric, so that dopants are not implanted into the entire left-hand LDD region but only into the region intended to form the left-hand contact region 13.

Fabrication of the device of FIG. 8 therefore requires the use of two implant masks, each of which is used to obtain one LDD region and its associated contact region, in two separate implantation steps.

FIG. 11 is a schematic sectional view of a diode according to another embodiment of the present invention. The diode of FIG. 11 is generally similar to the diode of FIG. 8, except that the LDD regions and contact regions are formed in a body diffusion 12 formed in the substrate 11.

For the diode structure of FIG. 8 or 11, the LDD regions partially overlap (underlie) the second polysilicon region, one on each side. The LDD regions of opposite conductivity types can thus be closely positioned together in the first polysilicon layer or body diffusion. If two highly doped regions (eg oppositely doped n+ and p+ regions) are butted together then the diode breakdown voltage and leakage current are very poor. The present invention makes possible butting together two more lightly doped regions (ie, the LDD regions), and providing a small gap between the LDD regions 5,14 gives greater flexibility to design a component with much better diode characteristics—higher breakdown voltage, and lower leakage. The heavily doped p+ and n+ source/drain regions are still used to give ohmic connection to the diode.

An “antifuse” diode may be obtained by making the gap between the two LDD regions 5,14 very small. In this case the reverse breakdown is destructive with higher applied voltage and current. After breakdown the device short circuits.

FIG. 13 is a schematic sectional view of a diode according another embodiment of the present invention. In this diode the first polysilicon region contains one LDD region 5, which is positioned away from the edges of the first polysilicon region. A contact region 7 is formed in the LDD region 5, having the same doping type but a higher carrier concentration to the LDD region 5. A contact region 13 is formed in the polysilicon layer, outside the LDD region 5; the contact region 13 may be formed at or near the boundary of the first polysilicon region 6. As seen in plan view, the second polysilicon region 9 “frames” the LDD region 5, such that the LDD region 5 is bounded on all sides by the second polysilicon region 9.

The second polysilicon region 9 is preferably electrically connected to the central contact 7 in this embodiment, to prevent the potential of the second polysilicon region 9 floating. (If desired this may be applied to other diode embodiments described in this application; for example, the second polysilicon region in the diode of FIG. 8 may be electrically connected to one contact to prevent its potential from floating.)

The process of manufacturing the diode of FIG. 13 is generally similar to the process of manufacturing the diode of FIG. 8, except that there is only one LDD implantation steps, using an appropriate implantation mask, to form the LDD region 5. As in the diode of FIG. 8, two separate implantation steps are required to form the contact regions 7,13 since these are of opposite conductivity type to one another and so require different dopants to be implanted. These are carried out using appropriate implantation masks so that, in each implantation step, the mask for the implantation step is formed by the spacer dielectric, the second polysilicon layer, and the additional mask. The implantation mask used to form the contact region 7 in the LDD region is the same implantation mask as used to form the LDD region.

FIG. 12 is a schematic sectional view of a diode according to another embodiment of the present invention. The diode of FIG. 12 is generally similar to the diode of FIG. 13, except that the LDD regions and contact regions are formed in a body diffusion 12 formed in the substrate 11

FIG. 14 is a schematic sectional view of a diode according to another embodiment of the present invention; a diode of this embodiment is a Schottky diode. The diode of FIG. 14 is similar to the diode of FIG. 13 in that the first polysilicon region 6 contains only one LDD region 5, which is positioned at or near the edges of the first polysilicon layer. A contact region 7 is formed in the LDD region 5, having the same doping type as but a higher carrier concentration than the LDD region 5. An electrode makes electrical contact with the first polysilicon region at a location away from the LDD region 5, and this electrode is connected to the second polysilicon layer.

For the polysilicon Schottky diode of FIG. 14, the use of the second polysilicon layer as a guard ring improves the component. The LDD implant is made in the semiconductor diffusion connection, with an ohmic high value contact implant outside it. The first polysilicon layer needs to be very lightly doped.

The second polysilicon region 9 may again have the form of a “frame”, for example formed as two parallel elongate strips that are closed off across their ends. If greater drive is required, the second polysilicon region 9 may be formed as a repeating array, for example with stripes arranged alternately as anode and cathode, as a grille structure, as a series of rings, etc.

FIG. 15 is a schematic sectional view of a varactor (variable capacitor) structure according to another embodiment of the present invention. The varactor structure of FIG. 15 is generally similar to the diode of FIG. 13, except that the second polysilicon layer 9 is electrically connected, by contact metal 2 and wiring 1, to the source/drain 13 at the outer boundary of the first polysilicon layer 6, rather than to the source/drain 7 positioned away from the outer boundary of the first polysilicon layer 6 as in FIG. 13. Hence, the second polysilicon layer 9 is electrically connected to the first polysilicon layer 6 via the source/drain 13 at the outer boundary of the first polysilicon layer 6.

A further difference is that the LDD region 5 is wider in the varactor (variable capacitor) structure of FIG. 15 than in the diode of FIG. 13, so that the gap between the LDD region 5 and the source/drain 13 at the outer boundary of the first polysilicon layer 6 is significantly smaller in the varactor structure of FIG. 15 than in the diode of FIG. 13.

Varactor structures are useful components in tuned circuits which vary capacitance with applied voltage. By overlapping a certain amount of the LDD region with the second polysilicon 9, and connecting the second polysilicon 9 to the body region of the lower polysilicon a varactor structure can be formed.

The second polysilicon layer is connected to the first polysilicon layer by wiring 1,2. However the opposite doping of the LDD region—the LDD region has the opposite conductivity type to the source/drain 13 at the outer boundary of the first polysilicon layer 6—combines the lateral junction diode with the vertical inter-polysilicon layer capacitance. Therefore the capacitance will be strongly dependent on the applied voltage. However the parasitic capacitance to the substrate will be minimal—this is just the polysilicon to substrate capacitance through the field oxide layer 4. Minimising the parasitic capacitance allows faster switching for the varactor structure. The small lateral separations between the LDD region and the source/drain 13 at the outer boundary of the first polysilicon layer 6 minimises the series resistance and hence allows a higher quality factor when used at high frequency.

The Schottky diode of FIG. 14 and the varactor structure of FIG. 15 may alternatively be implemented using a body diffusion layer, rather than the first polysilicon layer, as the active layer.

FIG. 9 is a schematic sectional view of a resistor according to another embodiment of the present invention. The resistor differs from the resistor of FIG. 6 in that two LDD regions 5 (having the same conductivity type as one another) are formed in the first polysilicon region, with each LDD region extending under the second polysilicon region.

In this embodiment the second polysilicon region is formed as a narrow stripe placed over, and extending generally orthogonally to, the first polysilicon region (which is also in the form of a stripe). This is shown in FIG. 10, which is a schematic perspective view of the resistor of FIG. 9.

In manufacture of the resistor, the LDD implant region may or may not extend across the width of the first polysilicon region 6. This will depend on the width of the second polysilicon region. As shown in FIG. 9, the LDD implantation extends slightly underneath the second polysilicon region 9 so that, if the second polysilicon region 9 is very narrow, the LDD region may extend across the first polysilicon region 6. If, however, the second polysilicon region 9 is relatively wide, two separate LDD regions are formed as shown in FIG. 9. The second polysilicon region 9 and the spacer dielectric 8 function as a mask for the source/drain implant.

Thus the first polysilicon layer is a high value resistor, depending on the doping levels of the LDD implant and the width of the second polysilicon stripe. Next, ohmic connections are created to both polysilicon stripes. By passing a high current through the upper polysilicon stripe it can be made very hot. The proximity of the upper polysilicon stripe to the lower polysilicon stripe enables good heat transfers to the lower polysilicon stripe, and the heating of the lower polysilicon stripe causes dopant diffusion in the lower stripe. This causes a permanent resistance change in the lower stripe—hence allowing a “trimming” action in the lower resistor. This can be useful to correct certain circuit offsets—eg in amplifiers.

Alternatively the heating action of the upper polysilicon stripe can be used as a simple high impedance current monitor thermal transducer. Resistance variation with temperature can be quite large in lightly doped semiconductors. The lower stripe resistance change will be pronounced as the temperature changes.

In another variant of the component the source and drain regions may be made of opposite conductivity type, as in the case of the antifuse diode described above. Then the heating element (the upper polysilicon stripe) acts on a diode rather than a resistor, causing an even more pronounced shift in properties of the lower polysilicon stripe with heating.

To increase the effect the device may be configured as a serpentine or meander heater element so that the number of stripes of high resistance (or diode) is multiplied.

The process sequence of making a CMOS process with two polysilicon layers which can be used to mask the n+ or p+ implant can also be exploited to offer devices which utilise the LDD implants. The second polysilicon allows larger areas than normally created to have LDD implants, without having a top-up doping from the heavy source-drain doping. This avoids the alternative methods where the LDD is implanted using a separate LDD mask.

Many new device structures are possible, with varying properties and uses. The benefit of the invention is that the LDD implants, which are usually only available at the edges of the transistor gate, are available for use in other areas, without the need for a special LDD mask. The only restriction is that the second polysilicon region must be positioned over part of the LDD implanted region.

The invention has been described above with reference to embodiments that incorporate one or more polysilicon layers. The invention is not however limited to this, and any embodiment of the invention may alternatively be implemented using amorphous silicon in place of the described polysilicon layer(s). In principle the invention may as a further alternative be implemented using a mixture of amorphous silicon and polysilicon layers (so that the embodiment of FIG. 6, as an example, could in principle be implemented using one polysilicon layer and one amorphous silicon layer).

1. A method of manufacturing a semiconductor device comprising, in sequence:
a) depositing a first silicon layer;
b) patterning the first silicon layer to obtain a first silicon region;
c) implanting a first dopant into a first part of the first silicon region thereby to form a lightly-doped diffusion zone in the first part of the first silicon region, the first part of the first silicon region defined using a first mask;
d) depositing a second silicon layer;
e) patterning the second silicon layer to obtain a second silicon region, the second silicon region extending over part of the lightly-doped diffusion zone; and
f) implanting a second dopant into a second part of the first silicon region, the second part of the first silicon region defined by the first mask and the second silicon region.

2. A method as claimed in claim 1 and further comprising initially doping the first silicon layer before implanting the first dopant.

3. A method as claimed in claim 1 wherein the first implantation step comprises forming a lightly-doped diffusion zone in the first part of the first silicon region.

4. A method as claimed in claim 1 wherein the first part of the first silicon region comprises less than the entire first silicon region.

5. A method as claimed in claim 1 wherein the second part of the first silicon region is wholly within the first part of the first silicon region.

6. A method as claimed in claim 1 and comprising depositing a first electrically insulating material adjacent to the second silicon region before implanting the second dopant, whereby the second part of the first silicon region is defined by the first mask, the second silicon region and the first electrically insulating material.

7. A method as claimed in claim 1 and comprising the further step of, before the step of depositing the second silicon layer, depositing a second electrically insulating layer over the first silicon region.

8. A method as claimed in claim 1 and further comprising:
f11) implanting a dopant into a third part of the first silicon region, the third part being different to the first part and different to the second part.

9. A method of manufacturing a semiconductor device comprising, in sequence:
a) forming a body diffusion in a substrate;
b) implanting a first dopant into a first part of the body diffusion, the first part of the body diffusion defined using a first mask;
c) depositing a silicon layer;
d) patterning the silicon layer to form a silicon region; and
e) implanting a second dopant into a second part of the body diffusion, the second part of the body diffusion being defined by the first mask and the silicon region.

10. A method as claimed in claim 9 wherein the first implantation step comprises forming a lightly-doped diffusion zone in the first part of the body diffusion.

11. A method as claimed in claim 9 wherein the first part of the body diffusion comprises less than the entire body diffusion.

12. A method as claimed in claim 9 wherein the second part of the body diffusion is wholly within the first part of the body diffusion.

13. A method as claimed in claims 9 and comprising depositing a first electrically insulating material adjacent to the second silicon region before implanting the second dopant, whereby the second part of the body diffusion is defined by the first mask, the second silicon region and the first electrically insulating material.

14. A method as claimed in claim 9 to and comprising the further step of, before the step of depositing the second silicon layer, depositing a second electrically insulating layer over the body diffusion.

15. A method as claimed in claim 6 wherein the first electrically insulating material and/or the second electrically insulating material comprise a dielectric material.

16. A method of manufacturing a semiconductor device comprising, in sequence:
a) forming a body diffusion in a substrate;
b) depositing a first silicon layer;
c) patterning the first silicon layer to form a first silicon region;
d) implanting a first dopant into a first part of the body diffusion, the first part of the body diffusion defined using a first mask and the first silicon region;
e) depositing a second silicon layer;
f) patterning the second silicon layer to form a second silicon region; and
g) implanting a second dopant into a second part of the body diffusion, the second part of the body diffusion being defined by the first mask and the second silicon region.

17. A method of manufacturing a semiconductor device comprising, in sequence:
a) depositing a first silicon layer;
b) patterning the first silicon layer to obtain a first silicon region;
c) implanting a first dopant into a first part of the first silicon region to obtain a lightly-doped diffusion region in the first part of the first silicon region;
d) depositing a second silicon layer;
e) patterning the second silicon layer to obtain a second silicon region; and
f) implanting a second dopant into a part of the lightly-doped diffusion region using the second silicon region as a mask.

18. A method as claimed in claim 17 and further comprising initially doping the first silicon layer before implanting the first dopant.

19. A method of manufacturing a semiconductor device comprising, in sequence:
a) forming a body diffusion in a substrate;
b) implanting a first dopant into a first part of the body diffusion to obtain a lightly-doped diffusion region in the first part of the body diffusion;
c) depositing a second silicon layer;
d) patterning the second silicon layer to obtain a second silicon region; and
e) implanting a second dopant into a part of the lightly-doped diffusion region using the second silicon region as a mask.

20. A device comprising: a semiconductor layer; a first doped region within the semiconductor layer; a second doped region within the first doped region; and a silicon layer disposed over a part of the semiconductor layer; wherein the silicon layer is disposed over a part of the first doped region but not over the second doped region.

21. A device as claimed in claim 20 wherein the semiconductor layer is another silicon layer.

22. A device as claimed in claim 20 wherein the semiconductor layer is a body diffusion.

23. A device as claimed in claim 20 wherein the second doped region has a higher carrier concentration than the first doped region.

24. A device as claimed in claim 23 wherein the first doped region is a lightly-doped diffusion region.

25. A device as claimed in claim 20 wherein the first doped region extends substantially laterally across the semiconductor layer.

26. A device as claimed in claim 20 and further comprising a first electrically insulating material disposed over the semiconductor layer and adjacent to the silicon layer, the first electrically insulating material extending over the first doped region but not over the second doped region thereby to form a sidewall spacer.

27. A device as claimed in claim 20 and further comprising a second electrically insulating material disposed between the semiconductor layer and the silicon layer.

28. A device as claimed in claim 26 wherein the first electrically insulating material and/or the second electrically insulating material comprise a dielectric material.

29. A device as claimed in claim 21 wherein the silicon layer and the another silicon layer are each strip-like, with the silicon layer being crossed with the another silicon layer.

30. A device as claimed in claim 22 and further comprising another silicon layer, wherein the another silicon layer extends over and substantially along side faces of the silicon layer.

31. A device as claimed in claim 20 to wherein the device is one of a resistor, a transistor, a diode or a varactor structure.
